(19) United States
(12) Patent Application Publication
(10) Pub. No.: US 2021/0313176 A1
(43) Pub. Date: Oct. 7, 2021

(54) SEMICONDUCTOR FORMATIONS

(71) Applicant: Hewlett-Packard Development Company, L.P., Spring, TX (US)

(72) Inventors: Robert Ionescu, Palo Alto, CA (US); Helen A. Holder, Palo Alto, CA (US); Jarrid Wittkopf, Palo Alto, CA (US)

(73) Assignee: Hewlett-Packard Development Company, L.P., Spring, TX (US)

(21) Appl. No.: 17/262,766

(22) PCT Filed: Nov. 8, 2018
(86) PCT No.: PCT/US2018/059864

§ 371 Date: Jan. 25, 2021

(51) Int. Cl. H01L 21/02; C09D 11/52; C01G 39/00; B41J 2/135; C09D 11/38

(52) U.S. Cl. CPC H01L 21/02568; C09D 11/52; C09D 11/38; C01G 39/006; B41J 2/135; H01L 21/02628

(57) ABSTRACT

A method may include ejecting, from a nozzle, a first printable ammonium-based chalcogenometalate fluid comprising a first dopant onto a substrate to form a layer of the first printable ammonium-based chalcogenometalate fluid; heating, at a first temperature, the layer of first printable ammonium-based chalcogenometalate fluid to dissipate the first printable ammonium-based chalcogenometalate fluid into a transition metal dichalcogenide having the form MX2 with the first dopant distributed therethrough; ejecting, from the nozzle, a second printable ammonium-based chalcogenometalate fluid comprising a second dopant onto the substrate to form a layer of the second printable ammonium-based chalcogenometalate fluid; and heating, at a second and higher temperature, the layers of first and second printable ammonium-based chalcogenometalate fluid.

### BACKGROUND

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a semiconductor having a thickness on the atomic scale.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a flowchart depicting a method according to an example of the principles described herein.

FIG. 2 is a block diagram of a printing device according to an example of the principles described herein.

FIG. 3 is a flowchart depicting a method of forming a semiconductor device according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a semiconductor with a thickness on the atomic scale. 2D semiconductors may be used in components for next generation electronics that have reduced form factors, for example.

In the examples presented herein, the semiconductors may be created using a printing device. By depositing a printable fluid such as an ammonium-based chalcogenometalate fluid onto a substrate, layers of the semiconductor may be formed. Printing these layers as individual layers may cause additional challenges where one layer is to be deposited onto another such as in the creation of the semiconductor. One challenge includes discontinuity in layer material between two layers. This may occur because the liquid forms of the layers may mix prior to any annealing or curing of these layers.

The present specification describes a method that includes ejecting, from a nozzle, a first printable ammonium-based chalcogenometalate fluid comprising a first dopant onto a substrate to form a layer of the first printable ammonium-based chalcogenometalate fluid; heating, at a first temperature, the layer of first printable ammonium-based chalcogenometalate fluid to dissipate the first printable ammonium-based chalcogenometalate fluid into a transition metal dichalcogenide having the form MX₂ with the first dopant distributed therethrough; ejecting, from the nozzle, a second printable ammonium-based chalcogenometalate fluid comprising a second dopant onto the substrate to form a layer of the second printable ammonium-based chalcogenometalate fluid; and heating, at a second and higher temperature, the layers of first and second printable ammonium-based chalcogenometalate fluid.

The present specification also describes a printing device that includes a nozzle to eject an amount of first and second printable ammonium-based chalcogenometalate fluids, the nozzle including a firing chamber to hold the amount of printable ammonium-based chalcogenometalate fluid; an opening; and an ejector to eject the amount of printable ammonium-based chalcogenometalate fluid through the opening; a reservoir to supply the first and second printable ammonium-based chalcogenometalate fluid to the nozzle; and a heat source to selectively heat the first and second printable ammonium-based chalcogenometalate fluids at two different temperatures after deposition by the nozzle; the first printable ammonium-based chalcogenometalate fluid comprising a first ammonium-based chalcogenometalate precursor, a first aqueous solvent, water, and a first dopant; and the second printable ammonium-based chalcogenometalate fluid comprising a second ammonium-based chalcogenometalate precursor, a second aqueous solvent, water, and a second dopant.

The present specification further describes a method of forming a semiconductor, including depositing a first printable ammonium-based chalcogenometalate fluid comprising a first dopant onto a substrate to form a layer of the first printable ammonium-based chalcogenometalate fluid; heating the layer of first printable ammonium-based chalcogenometalate fluid to dissipate the first printable ammonium-based chalcogenometalate fluid into a transition metal dichalcogenide having the form MX₂ with the first dopant distributed therethrough; depositing a second printable ammonium-based chalcogenometalate fluid comprising a second dopant onto the substrate to form a layer of the second printable ammonium-based chalcogenometalate fluid; heating the layer of second printable ammonium-based chalcogenometalate fluid to dissipate the second printable ammonium-based chalcogenometalate fluid into a transition metal dichalcogenide having the form MX₂ with the second dopant distributed therethrough; depositing the first printable ammonium-based chalcogenometalate fluid over the second printable ammonium-based chalcogenometalate fluid; and heating the layers to a temperature to convert the first and second printable ammonium-based chalcogenometalate fluids into a semiconductor state.

As used in the present specification and in the appended claims, the term “chalcogenometalate” may refer to transition metal thiometalates, or transitional metal-chalcogen compounds.

As used in the present specification and in the appended claims, the term “ammonium-based” may refer to a compound that includes the molecule NHa.

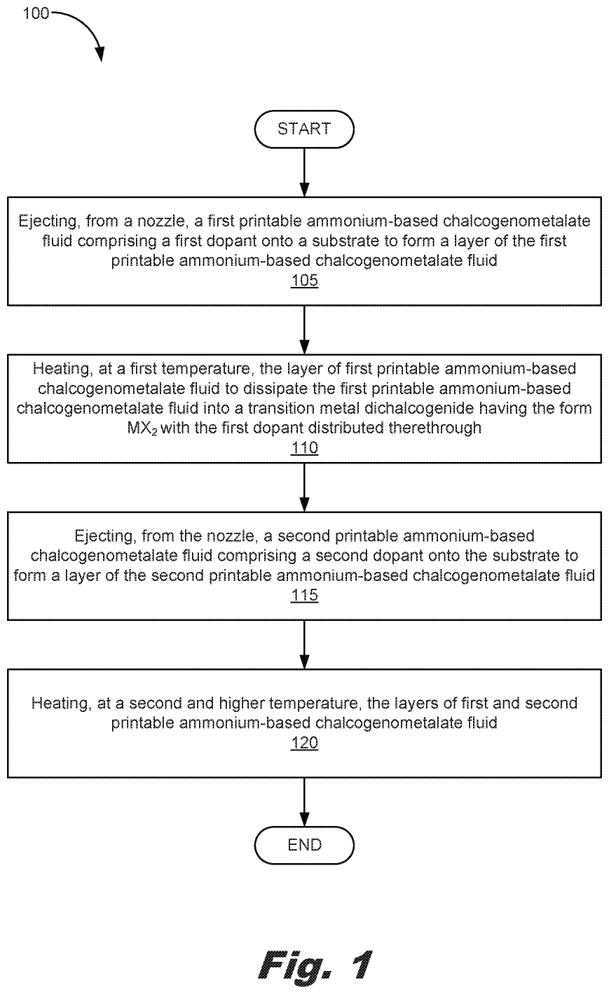

Turning now to the figures, FIG. 1 is a diagram of a flowchart describing a method (100) according to an example of the principles described herein. The method (100) may include ejecting (105), from a nozzle, a first printable ammonium-based chalcogenometalate fluid comprising a first dopant onto a substrate to form a layer of the first printable ammonium-based chalcogenometalate fluid. In any example presented herein, the nozzle may be part of any printing device and/or print cartridge used to eject (105) an amount of fluid onto a substrate. In an example, the nozzle may receive the fluid from a reservoir fluidically coupled to the nozzle. In the example where the nozzle forms part of a cartridge, the reservoir may be formed within the reservoir and be directly fluidically coupled to the nozzle. In other examples, the reservoir may be offline from the nozzle and fluidically coupled to the nozzle using a tube.

In any example described herein, the nozzle may eject (105) a first printable ammonium-based chalcogenometalate fluid. The nozzle may include additional devices such as an ejector and a firing chamber. The ejector may be any type of device that pushes an amount of the printable ammonium-based chalcogenometalate fluid from the firing chamber and out of the orifice of the nozzle. Example of ejectors may include piezoelectric ejection devices as well as resistive ejection devices. In the latter, the resistive ejection device may form a vapor bubble within the firing chamber of the nozzle, which vapor bubble ejects an amount of the printable ammonium-based chalcogenometalate fluid through the orifice of the nozzle.

In an example, the first printable ammonium-based chalcogenometalate fluid may include an ammonium-based chalcogenometalate precursor. In an example, the ammonium-based chalcogenometalate precursor may have the form (NH₄)₂MX₄. In this example, “M” is a transition metal as defined on a periodic table. Specific examples of transition metals include molybdenum and tungsten; however, other transition metals may be implemented as well. The “X” is a chalcogen atom as defined on the periodic table. Examples of chalcogens include oxygen, sulfur, selenium, and tellurium. Specific examples of ammonium-based chalcogenometalate precursors having the form (NH₄)₂MX₄ that may be found in the first printable ammonium-based transition metal fluid include ammonium tetrathiotungstate, (NH₄)₂WS₄, and ammonium tetrathiomolybdate, (NH₄)₂MoS₄.

While specific reference is made herein to particular ammonium-based chalcogenometalate precursors, a variety of ammonium-based chalcogenometalate precursors may be used. This ammonium-based chalcogenometalate precursor can be developed into any printable ammonium-based chalcogenometalate fluid, or an ammonium-based chalcogenometalate ink, and printed directly on substrates such as a metallic substrate.

The first printable ammonium-based chalcogenometalate fluid may include an aqueous solvent. The aqueous solvent dissolves the ammonium-based chalcogenometalate precursor which may be introduced into the first printable ammonium-based chalcogenometalate fluid in a powder form. The aqueous solvent may be any type of solvent including dimethyl sulfoxide (DMSO); dimethylformamide (DMF); N-methyl-20prrolidone (NMP); and 1,2-Hexanediol, among other -diol based solvents. While specific reference is made to particular aqueous solvents, a variety of aqueous solvents may be used, which solvents may be selected based on the ammonium-based chalcogenometalate precursor that is used.

The first printable ammonium-based chalcogenometalate fluid also includes water. The aqueous solvent and water may be mixed in any variety of ratios to achieve a desired printable concentration. For example, the aqueous solvent and water may be found in a ratio of 2 to 3. However, any desired mixture ratio may be used to achieve different properties, such as different viscosities.

In some examples, the various components of the first printable ammonium-based chalcogenometalate fluid, i.e., the ammonium-based chalcogenometalate precursor, the aqueous solvent, the water and the dopant, as well as the amounts and ratios of each component, may be selected based on the substrate onto which the first printable ammonium-based chalcogenometalate fluid is to be printed. In other words, the first printable ammonium-based chalcogenometalate fluid can easily be printed on numerous substrates. Examples of substrates that can be printed on include graphene, glass, polyethylene terephthalate, aluminum, quartz, sapphire, silicon, silicon dioxide, copper, nickel, ceramics, and gold. As mentioned herein, the specific composition and mixture of the first printable ammonium-based chalcogenometalate fluid may be completely or partially dependent upon the particular substrate selected.

The first printable ammonium-based chalcogenometalate fluid may also include a dopant. The dopant may be any trace impurity element represented on the periodic table of elements that is added into the first printable ammonium-based chalcogenometalate fluid in order to alter the operating characteristics of the semiconductor. In specific examples, the dopant may be any one of F4TCNQ (C₁₂F4N₄); tetracyanoquinodimethane (TCNQ); 1-Ethyl-3-methylimidazolium bis(trifluoromethylsulfonyl)imide ([EMIM]-[TFSI]); C₂₀H₂₈N₄O₄ (PDPP3T); C₄H₄S (thiophene); and NADA. In a specific example, F4TCNQ (C₁₂F4N₄) may be used as a p-type dopant. In an example, NADA may be used as an n-type dopant. Other dopants include, but are not limited to, boron (B), arsenic (As), phosphorus (P), antimony (Sb), aluminum (Al), gallium (GA), sulfur (S), selenium (Se), tellurium (Te), silicon (Si), germanium (Ge), magnesium (Mg), zinc (Zn), cadmium (Cd), erbium (Er), europium (Eu), neodymium (Nd), holmium (Ho), and neodymium yttrium aluminum garnets (YAGs), among others.

By including the dopant within the first printable ammonium-based chalcogenometalate fluid, any layer of any semiconductor may be enhanced using the specific capabilities of that dopant used. In an example, the first printable ammonium-based chalcogenometalate fluid with its dopant may be printed on the substrate using a printing device such as an inkjet printing device as described herein. The use of the printing device may allow the specific printing of any dopant material on any layer or portion of layer at any point. Additionally, such a printing process may be scaled to accommodate any individual size of project or semiconductor.

The method (100) may include heating (110), at a first temperature, the layer of first printable ammonium-based chalcogenometalate fluid to dissipate the first printable ammonium-based chalcogenometalate fluid into a transition metal dichalcogenide having the form MX₂ with the first dopant distributed therethrough. In this example, the heating (110) of the first printable ammonium-based chalcogenometalate fluid causes the first printable ammonium-based chalcogenometalate fluid from a MoS₄ to a MoS_{4-y} state (i.e., MoS₃ or MoS₂ state: a transition metal dichalcogenide or transition metal trichalcogenide). In this specific example, the first printable ammonium-based chalcogenometalate fluid has been hardened or otherwise prevented from being incorporated into any subsequent layer deposited over the first printable ammonium-based chalcogenometalate fluid. This specifically prevents any dopants within any of the layers from mixing thereby preventing any reduction in the efficiency of the created semiconductor. This initial heating process may increase the efficiency of the semiconductor system by reducing the time used in the heating processes and, thereby, increasing the formation time of the semiconductor.

The method (100) may include ejecting (115), from the nozzle, a second printable ammonium-based chalcogenometalate fluid comprising a second dopant onto the substrate to form a layer of the second printable ammonium-based chalcogenometalate fluid. Similar to the first printable ammonium-based chalcogenometalate fluid, the second printable ammonium-based chalcogenometalate fluid may include a second dopant along with, in some examples, an ammonium-based chalcogenometalate precursor, an aqueous solvent, water, and a second dopant. With the second printable ammonium-based chalcogenometalate fluid, the semiconductor may be made with either a distinct p-type or n-type dopant based on the type of dopant used in the first printable ammonium-based chalcogenometalate fluid.

The method (100) may include heating (120), at a second and higher temperature, the layers of first and second printable ammonium-based chalcogenometalate fluid. In a specific example, the first printable ammonium-based chalcogenometalate fluid may be heated to a temperature at or between 280 and 500 degrees Celsius. When each of the layers of first printable ammonium-based chalcogenometalate fluid and/or second printable ammonium-based chalcogenometalate fluid have been heated to this temperature, a second and higher temperature may be applied to the entire stack of layers. In an example, the second and higher temperature may be at or between 700 and 1,000 degrees Celsius. This second and higher temperature fully converts the layers of the first printable ammonium-based chalcogenometalate fluid and second printable ammonium-based chalcogenometalate fluid to a semiconductor state. In an example, the second and higher temperature may cause the MoS₃ into MoS₂. This method (100) develops defined layers with no mixing along any junction between the layers of the different materials ejected (105, 115) from the nozzles.

In a specific example, the method (100) described herein may be conducted by a printing system that includes, in addition to the nozzle, a heat source. In this example, the printing device may cause the nozzle to traverse over the substrate followed by the heat source that heats (110, 120) the layers deposited by the nozzle. The nozzle and heat source may traverse over the substrate independently of each other or together.

In any example presented herein, the method (100) may include the ejection (105, 115) of any additional layers of either of the first printable ammonium-based chalcogenometalate fluid or second printable ammonium-based chalcogenometalate fluid. In this example, each layer may be heated (110) to a temperature at or between 280 and 500 degrees Celsius. In these examples, the selective ejection and heating of these layers may allow for the creation of a p-type or n-type semiconductor based on which layers with which dopants are ejected.

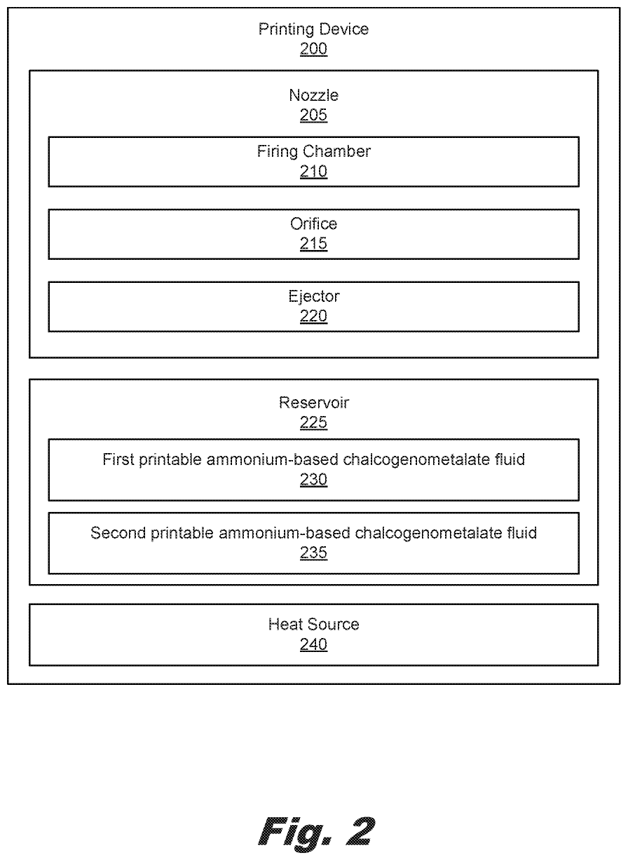

FIG. 2 is a block diagram of a printing device (200) according to an example of the principles described herein. In this example, the printing device (200) may include a nozzle (205), a reservoir (225) fluidically coupled to the nozzle (205), and a heat source (240). The nozzle (205), reservoir (225), and heat source (240) may be formed integrally into the printing device (200). In an example, the reservoir (225) may be placed offline and separate from the nozzle (205). Similarly, the heat source (240) may be either mechanically coupled with the nozzle (205) or mechanically independent of the nozzle (205).

The nozzle (205) may be coupled to a mechanical arm that allows the nozzle (205) to traverse over a substrate onto which the nozzle (205) ejects an amount of fluid thereon. The nozzle (205) may be directed to mechanically traverse the substrate as a consequence of execution of computer readable program code executed by a processor associated with the printing device (200). In an example, the ejection of the first printable ammonium-based chalcogenometalate fluid and second printable ammonium-based chalcogenometalate fluid as described herein is also a consequence of the execution of computer readable program code executed by the processor. Specifically, signals may be sent to an ejector (220) formed within a firing chamber (210) associated with the nozzle (205). The first or second printable ammonium-based chalcogenometalate fluid may then be pushed from the firing chamber (210) and through the orifice (215) of the nozzle (205). As described herein, the ejector may be one of either a piezoelectric ejection device or a thermoresistive ejection device. In the example where the ejector (220) is a piezoelectric ejection device, application of a voltage to the piezoelectric device causes the piezoelectric device to expand causing increased pressure within the firing chamber (210). The fluid within the firing chamber (210) is then pushed out of the orifice (215) of the nozzle (205) and onto the substrate. In the example where the ejector (220) is a thermoresistive ejection device, a voltage is applied to the thermoresistive ejection device. Once the voltage is applied to the thermoresistive ejection device, heat created by the thermoresistive ejection device forms a vapor bubble within the firing chamber (210) of the nozzle (205). This vapor bubble, in turn, ejects an amount of the first and/or second printable ammonium-based chalcogenometalate fluid through the orifice (215) in the nozzle (205).

As described herein, the reservoir (225) may maintain any amount of the first printable ammonium-based chalcogenometalate fluid (230) and/or second printable ammonium-based chalcogenometalate fluid (235). As described herein, the first printable ammonium-based chalcogenometalate fluid (230) may include an ammonium-based chalcogenometalate precursor, an aqueous solvent, water, and a first dopant. Similarly, the second printable ammonium-based chalcogenometalate fluid (235) may include an ammonium-based chalcogenometalate precursor, an aqueous solvent, water, and a second dopant.

The printing device (200) may include a heat source (240). In an example, the heat source (240) is formed into part of a substrate transport assembly used to hold and/or transport the substrate under the nozzle (205). In this example, the heat source (240) may be a thermoresistive device that receives a voltage to create heat under or next to the substrate onto which the first printable ammonium-based chalcogenometalate fluid (230) and/or second printable ammonium-based chalcogenometalate fluid (235) are ejected onto. In an example, the heat source (240) is a heat lamp. In this example, the heat lamp may provide variable levels of the temperatures to the first printable ammonium-based chalcogenometalate fluid (230) and/or second printable ammonium-based chalcogenometalate fluid (235) as described herein. In this example, the heat lamp may heat the first printable ammonium-based chalcogenometalate fluid (230) and/or second printable ammonium-based chalcogenometalate fluid (235) to a first and, distinct, second temperature. The first temperature may be at or between 280 and 500 degrees Celsius. The second temperature may be at or between 700 and 1,000 degrees Celsius.

In an example, the printing device (200) may form part of a printing system that includes a computing device communicatively coupled to the printing device (200). Examples of computing devices include servers, desktop computers, laptop computers, personal digital assistants (PDAs), mobile devices, smartphones, gaming systems, and tablets, among other electronic devices.

The printing device (200) may be utilized in any data processing scenario including, stand-alone hardware, mobile applications, through a computing network, or combinations thereof. Further, the printing device (200) may be used in a computing network, a public cloud network, a private cloud network, a hybrid cloud network, other forms of networks, or combinations thereof. In one example, the methods provided by the printing device (200) are provided as a service over a network by, for example, a third party. In this example, the service may comprise, for example, the following: a Software as a Service (SaaS) hosting a number of applications; a Platform as a Service (PaaS) hosting a computing platform comprising, for example, operating systems, hardware, and storage, among others; an Infrastructure as a Service (IaaS) hosting equipment such as, for example, servers, storage components, network, and components, among others; application program interface (API) as a service (APlaaS), other forms of network services, or combinations thereof.

To achieve its functionality, the computing device and/or printing device (200) includes various hardware components. Among these hardware components may be a number of processors, a number of data storage devices, a number of peripheral device adapters, and a number of network adapters. These hardware components may be interconnected through the use of a number of busses and/or network connections. In one example, the processor, data storage device, peripheral device adapters, and a network adapter may be communicatively coupled via a bus.

The processor may include the hardware architecture to retrieve executable code from the data storage device and execute the executable code. The executable code may, when executed by the processor, cause the processor to implement at least the functionality of the methods described herein. In the course of executing code, the processor may receive input from and provide output to a number of the remaining hardware units.

The data storage device may store data such as executable program code that is executed by the processor or other processing device. The data storage device may specifically store computer code representing a number of applications that the processor executes to implement at least the functionality described herein.

The data storage device may include various types of memory modules, including volatile and nonvolatile memory. For example, the data storage device of the present example includes Random Access Memory (RAM), Read Only Memory (ROM), and Hard Disk Drive (HDD) memory. Many other types of memory may also be utilized, and the present specification contemplates the use of many varying type(s) of memory in the data storage device as may suit a particular application of the principles described herein. In certain examples, different types of memory in the data storage device may be used for different data storage needs. For example, in certain examples the processor may boot from Read Only Memory (ROM), maintain nonvolatile storage in the Hard Disk Drive (HDD) memory, and execute program code stored in Random Access Memory (RAM).

The data storage device may comprise a computer readable medium, a computer readable storage medium, or a non-transitory computer readable medium, among others. For example, the data storage device may be, but not limited to, an electronic, magnetic, optical, electromagnetic, infrared, or semiconductor system, apparatus, or device, or any suitable combination of the foregoing. More specific examples of the computer readable storage medium may include, for example, the following: an electrical connection having a number of wires, a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store computer usable program code for use by or in connection with an instruction execution system, apparatus, or device. In another example, a computer readable storage medium may be any non-transitory medium that can contain, or store a program for use by or in connection with an instruction execution system, apparatus, or device.

The hardware adapters in the computing device and/or printing device (200) enable the processor to interface with various other hardware elements, external and internal to the computing device and/or printing device (200). For example, the peripheral device adapters may provide an interface to input/output devices, such as, for example, display device, a mouse, or a keyboard. The peripheral device adapters may also provide access to other external devices such as an external storage device, a number of network devices such as, for example, servers, switches, and routers, client devices, other types of computing devices, and combinations thereof.

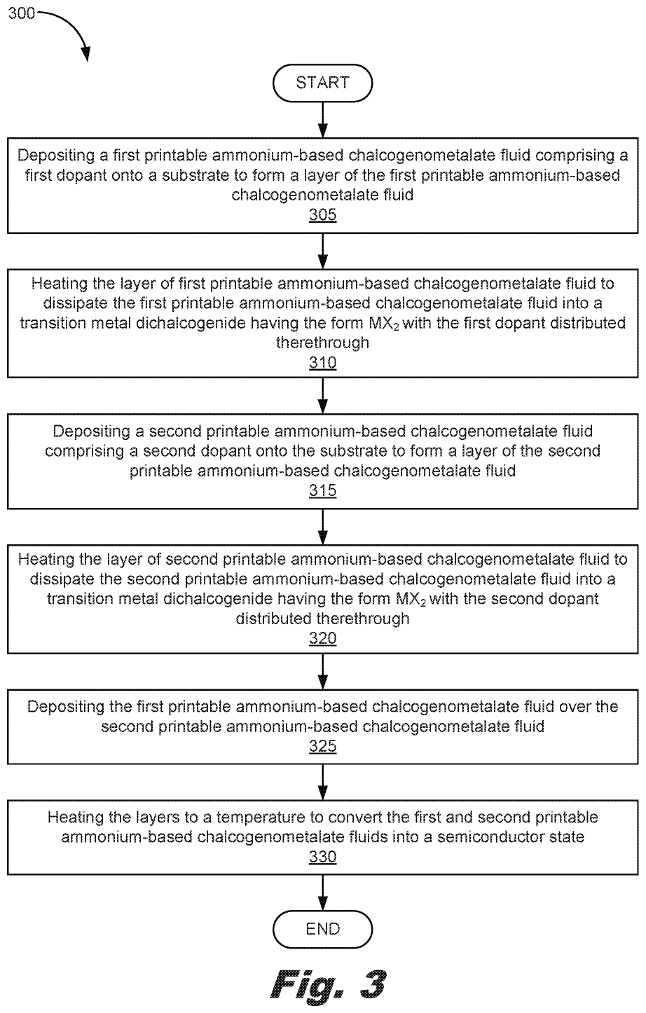

FIG. 3 is a flowchart depicting a method (300) of forming a semiconductor according to an example of the principles described herein. The method (300) may include depositing (305) a first printable ammonium-based chalcogenometalate fluid (230) that includes a first dopant onto a substrate to form a layer of the first printable ammonium-based chalcogenometalate fluid. The method (300) may continue with heating (310) the first printable ammonium-based chalcogenometalate fluid (230) to dissipate the first printable ammonium-based chalcogenometalate fluid (230) into a transition metal dichalcogenide having the form MX₂ with the first dopant distributed therethrough. In this example, the method (300) may continue with depositing (315) a second printable ammonium-based chalcogenometalate fluid (235) comprising a second dopant onto the substrate to form a layer of the second printable ammonium-based chalcogenometalate fluid.

The method (300) may then include heating (320) the layer of second printable ammonium-based chalcogenometalate fluid (235) to dissipate the second printable ammonium-based chalcogenometalate fluid (235) into a transition metal dichalcogenide having the form MX₂ with the second dopant distributed therethrough. As described herein, the heating (310, 320) of the first printable ammonium-based chalcogenometalate fluid (230) and second printable ammonium-based chalcogenometalate fluid (235) causes these layers to be hardened preventing the mixing of the different fluids (230, 235) when deposited by the nozzle (205) of the printing device (200).

The method (300) may comprise depositing (325) the first printable ammonium-based chalcogenometalate fluid (230) over the second printable ammonium-based chalcogenometalate fluid (235). In an example, this additional layer of first printable ammonium-based chalcogenometalate fluid (230) may be heated to the same temperature as that applied to the other deposited (305, 315) layers. In another example, the entire stack of layers may be heated (330) to a temperature to convert the first and second printable ammonium-based chalcogenometalate fluids into a semiconductor state. As described herein, the heating (330) process of these layers may be accomplished using the heat source (240) described herein. The final heating (330) process includes heating (330) all layers to a temperature at or between 700 and 1,000 degrees Celsius whereas the other heating processes may include heating (310, 320) the individual layers to a temperature at or between 280 and 500 degrees Celsius.

Aspects of the present system and method are described herein with reference to flowchart illustrations and/or block diagrams of methods, apparatus (systems) and computer program products according to examples of the principles described herein. Each block of the flowchart illustrations and block diagrams, and combinations of blocks in the flowchart illustrations and block diagrams, may be implemented by computer usable program code. The computer usable program code may be provided to a processor of a general-purpose computer, special purpose computer, or other programmable data processing apparatus to produce a machine, such that the computer usable program code, when executed via, for example, the processor of the computing device, printing device (200), or other programmable data processing apparatus, implement the functions or acts specified in the flowchart and/or block diagram block or blocks. In one example, the computer usable program code may be embodied within a computer readable storage medium; the computer readable storage medium being part of the computer program product. In one example, the computer readable storage medium is a non-transitory computer readable medium.

The specification and figures describe methods and printing devices used to print semiconductor devices such as transistors. The printing device and methods described herein provide for the printing of uniform stacks of semiconductive materials with dopants. By heating the individual layers to a temperature at or between 280 and 500 degrees Celsius, any fluids of the subsequent layers deposited on the previous layers by the nozzle of the printing device do not mix with the fluids of the previously laid layers. This allows for a myriad of heterostructures to be produced that are made of various materials as described herein. Additionally, by heating each of the deposited layers to this intermediate temperature, the deposition of all or multiple layers may be accomplished prior to an application of a semiconductor-forming heat. This increases the speed at which the layers may be deposited on each other thereby increasing the manufacturing process. As a result, this may reduce the time and cost associated with forming these semiconductor devices. Additionally, the components of the layers do not mix amongst themselves assuring an increased quality of printed semiconductive device is created. The scalability of the methods via the use of the printing device allows for any number or size of semiconductors to be printed.

The preceding description has been presented to illustrate and describe examples of the principles described. This description is not intended to be exhaustive or to limit these principles to any precise form disclosed. Many modifications and variations are possible in light of the above teaching.

What is claimed is:

1. A method comprising:
ejecting, from a nozzle, a first printable ammonium-based chalcogenometalate fluid comprising a first dopant onto a substrate to form a layer of the first printable ammonium-based chalcogenometalate fluid;
heating, at a first temperature, the layer of first printable ammonium-based chalcogenometalate fluid to dissipate the first printable ammonium-based chalcogenometalate fluid into a transition metal dichalcogenide having the form MX₂ with the first dopant distributed therethrough;
ejecting, from the nozzle, a second printable ammonium-based chalcogenometalate fluid comprising a second dopant onto the substrate to form a layer of the second printable ammonium-based chalcogenometalate fluid; and
heating, at a second and higher temperature, the layers of first and second printable ammonium-based chalcogenometalate fluid.

2. The method of claim 1, wherein ejecting, from the nozzle, the first printable ammonium-based chalcogenometalate fluid comprises:
heating an ejector within a firing chamber of the nozzle;
forming a vapor bubble within the firing chamber of the nozzle, which vapor bubble ejects an amount of the first printable ammonium-based chalcogenometalate fluid through an orifice in the nozzle.

3. The method of claim 1, comprising heating the layer of second printable ammonium-based chalcogenometalate fluid to dissipate the second printable ammonium-based chalcogenometalate fluid into a transition metal dichalcogenide having the form MX₂ with the second dopant distributed therethrough.

4. The method of claim 1, wherein heating the layer of the first printable ammonium-based chalcogenometalate fluid comprises heating the layer of the first printable ammonium-based chalcogenometalate fluid to a temperature of 280-500 degrees Celsius.

5. The method of claim 1, comprising heating the layer of second printable ammonium-based chalcogenometalate fluid to a temperature of 280-500 degrees Celsius.

6. The method of claim 5, comprising ejecting a second layer of the first printable ammonium-based chalcogenometalate fluid and heating the first layer of the first printable ammonium-based chalcogenometalate fluid, the layer of second printable ammonium-based chalcogenometalate fluid, and the second layer of the first printable ammonium-based chalcogenometalate fluid to a temperature of 700-1000 degrees Celsius.

7. The method of claim 1, wherein the substrate is selected from the group consisting of: graphene, glass, polyethylene terephthalate, aluminum, quartz, sapphire, silicon, silicon dioxide, copper, nickel, ceramics, and gold.

8. The method of claim 1, wherein the first and second printable ammonium-based chalcogenometalate fluid comprises an ammonium-based chalcogenometalate precursor and wherein the ammonium-based chalcogenometalate precursor is formed by combining a fluid having the form (NH₄)₂MO_{y} with a gas having the form H₂X where:
M is the transition metal;
Y is a numeric value;
X is a chalcogen selected from the group consisting of:
sulfur;
selenium; and
tellurium.

9. A printing device, comprising:
a nozzle to eject an amount of first and second printable ammonium-based chalcogenometalate fluids, the nozzle comprising:
a firing chamber to hold the amount of printable ammonium-based chalcogenometalate fluid;
an orifice; and
an ejector to eject the amount of printable ammonium-based chalcogenometalate fluid through the orifice;
a reservoir to supply the first and second printable ammonium-based chalcogenometalate fluid to the nozzle; and
a heat source to selectively heat the first and second printable ammonium-based chalcogenometalate fluids at two different temperatures after deposition by the nozzle;
the first printable ammonium-based chalcogenometalate fluid comprising a first ammonium-based chalcogenometalate precursor, a first aqueous solvent, water, and a first dopant; and
the second printable ammonium-based chalcogenometalate fluid comprising a second ammonium-based chalcogenometalate precursor, a second aqueous solvent, water, and a second dopant.

10. The printing device of claim 9, wherein the first and second ammonium-based chalcogenometalate precursors have the form (NH₄)₂MX₄ wherein:
M is a transition metal; and
X is a chalcogen.

11. The printing device of claim 9, wherein the first and second ammonium-based chalcogenometalate precursors are selected from the group consisting of:
ammonium tetrathiotungstate; and
ammonium tetrathiomolybdate.

12. The printing device of claim 9, wherein the first and second dopants are selected from the group consisting of:
F₄TCNQ;
TCNQ;
[EMIM]-[TFSI];
PDPP3T;
thiophene;
MoS₂;
WS₂; and
NADA.

13. The printing device of claim 9, comprising a heat source to consecutively heat layers of the first and second printable ammonium-based chalcogenometalate fluid as they are ejected.

14. A method of forming a semiconductor device, comprising:
depositing a first printable ammonium-based chalcogenometalate fluid comprising a first dopant onto a substrate to form a layer of the first printable ammonium-based chalcogenometalate fluid;
heating the layer of first printable ammonium-based chalcogenometalate fluid to dissipate the first printable ammonium-based chalcogenometalate fluid into a transition metal dichalcogenide having the form MX₂ with the first dopant distributed therethrough;
depositing a second printable ammonium-based chalcogenometalate fluid comprising a second dopant onto the substrate to form a layer of the second printable ammonium-based chalcogenometalate fluid;
heating the layer of second printable ammonium-based chalcogenometalate fluid to dissipate the second printable ammonium-based chalcogenometalate fluid into a transition metal dichalcogenide having the form MX₂ with the second dopant distributed therethrough;
depositing the first printable ammonium-based chalcogenometalate fluid over the second printable ammonium-based chalcogenometalate fluid; and
heating the layers to a temperature to convert the first and second printable ammonium-based chalcogenometalate fluids into a semiconductor state.

15. The method of claim 14, wherein the first and second ammonium-based chalcogenometalate fluids comprises first and second ammonium-based chalcogenometalate precursors, respectively, having the form (NH₄)₂MX₄, where:
M is a transition metal; and
X is a chalcogen.
